(19) United States
(12) Patent Application Publication
(10) Pub. No.: US 2018/0047667 A1
(43) Pub. Date: Feb. 15, 2018

(54) SEMICONDUCTOR DEVICE

(71) Applicant: Renesas Electronics Corporation, Tokyo (JP)

(72) Inventors: Shinichi UCHIDA, Tokyo (JP); Yasutaka NAKASHIBA, Ibaraki (JP)

(21) Appl. No.: 15/619,703

(22) Filed: Jun. 12, 2017

(30) Foreign Application Priority Data
Aug. 10, 2016 (JP) 2016-157966

(51) Int. Cl. H01L 23/522; H01L 49/02

(52) U.S. Cl. CPC H01L 23/5227; H01L 28/10; H01L 23/5226

(57) ABSTRACT

A semiconductor device is provided with a SOI substrate including a semiconductor substrate, a BOX layer on the semiconductor substrate, and a semiconductor layer on the BOX layer, a multilayer wiring formed over a main surface of the SOI substrate, and an inductor comprised of the multilayer wiring. In a region located below the inductor, the BOX layer and the semiconductor layer are separated into a plurality of regions by an element isolation portion, and a dummy gate electrode is formed on a part of the semiconductor layer, which is located in each of the plurality of regions, via a dummy gate insulating film.

### CROSS-REFERENCE TO RELATED APPLICATION

The present application claims priority from Japanese Patent Application No. 2016-157966 filed on Aug. 10, 2016, the content of which is hereby incorporated by reference into this application.

### TECHNICAL FIELD OF THE INVENTION

The present invention relates to a semiconductor device, and is suitably applied to, for example, a semiconductor device formed on a SOI (Silicon on Insulator) substrate and including an inductor.

### BACKGROUND OF THE INVENTION

Japanese Unexamined Patent Application Publication No. 2013-110351 (Patent Document 1) discloses a technique of suppressing generation of eddy current in a semiconductor substrate located below an inductor, with the semiconductor substrate being left in openings provided in an element isolation film located below the inductor.

### SUMMARY OF THE INVENTION

An inductor provided in a semiconductor device is desired to have high Q (Quality Factor). For the increase of the Q of the inductor, it is necessary to reduce eddy current generated in a semiconductor substrate located below the inductor.

For example, Patent Document 1 mentioned above describes a technique of suppressing generation of eddy current by dividing a well into plural parts in a region located below an inductor. However, since a dummy gate electrode is connected to a dummy diffusion layer formed on a semiconductor substrate, back electromotive force increases due to impedance of the dummy gate electrode and the dummy diffusion layer when eddy current is generated in the well, and there is concern about the degradation of characteristics of the inductor.

The other objects and novel characteristics of the present invention will be apparent from the description of the present specification and the accompanying drawings.

A semiconductor device according to an embodiment is provided with a SOI substrate including a semiconductor substrate, a BOX layer on the semiconductor substrate, and a semiconductor layer on the BOX layer, a multilayer wiring formed over a main surface of the SOI substrate, and an inductor comprised of the multilayer wiring. In a region located below the inductor, the BOX layer and the semiconductor layer are separated into a plurality of regions by an element isolation portion, and a dummy gate electrode is formed on a part of the semiconductor layer, which is located in each of the plurality of regions, via a dummy gate insulating film.

According to an embodiment, it is possible to improve the characteristics of the inductor provided in the semiconductor device.

### BRIEF DESCRIPTIONS OF THE DRAWINGS

FIG. 1 is a cross-sectional view showing a semiconductor device according to a first embodiment;

FIG. 2 is a plan view showing an inductor according to the first embodiment;

FIG. 3 is a plan view showing a dummy element region located below the inductor according to the first embodiment;

FIG. 4 is a cross-sectional view showing a manufacturing process of the semiconductor device according to the first embodiment;

FIG. 5 is a cross-sectional view showing the manufacturing process of the semiconductor device continued from FIG. 4;

FIG. 6 is a cross-sectional view showing the manufacturing process of the semiconductor device continued from FIG. 5;

FIG. 7 is a cross-sectional view showing the manufacturing process of the semiconductor device continued from FIG. 6;

FIG. 8 is a cross-sectional view showing the manufacturing process of the semiconductor device continued from FIG. 7;

FIG. 9 is a plan view showing an inductor according to a second embodiment; and

FIG. 10 is a plan view showing a dummy element region located below the inductor according to the second embodiment.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or apart of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable.

Further, it is needless to say that the components (including element steps) described in the following embodiments are not always indispensable unless otherwise stated or except the case where the components are apparently indispensable in principle.

In addition, it is needless to say that the phrases “made of A”, “formed of A”, “have A” and “include A” are not intended to exclude elements other than A unless it is particularly specified that A is the only element from the context. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the values, range, and the like mentioned above.

Also, components having the same function are denoted by the same reference characters in principle throughout the drawings for describing the embodiments, and the repetitive description thereof is omitted. The size of respective portions does not correspond to that of an actual device in sectional views and plan views, and a specific portion is shown in a relatively enlarged manner in some cases so as to make the drawings easy to see. Further, a specific portion is shown in a relatively enlarged manner in some cases so as to make the drawings easy to see even when the plan view and the cross-sectional view correspond to each other. In addition, in some drawings used in the following embodiments, hatching is omitted even in a cross-sectional view so as to make the drawings easy to see, and hatching is used even in a plan view so as to make the drawings easy to see.

Hereinafter, embodiments of the present invention will be described in detail based on drawings.

### First Embodiment

<<Configuration of Semiconductor Device>>

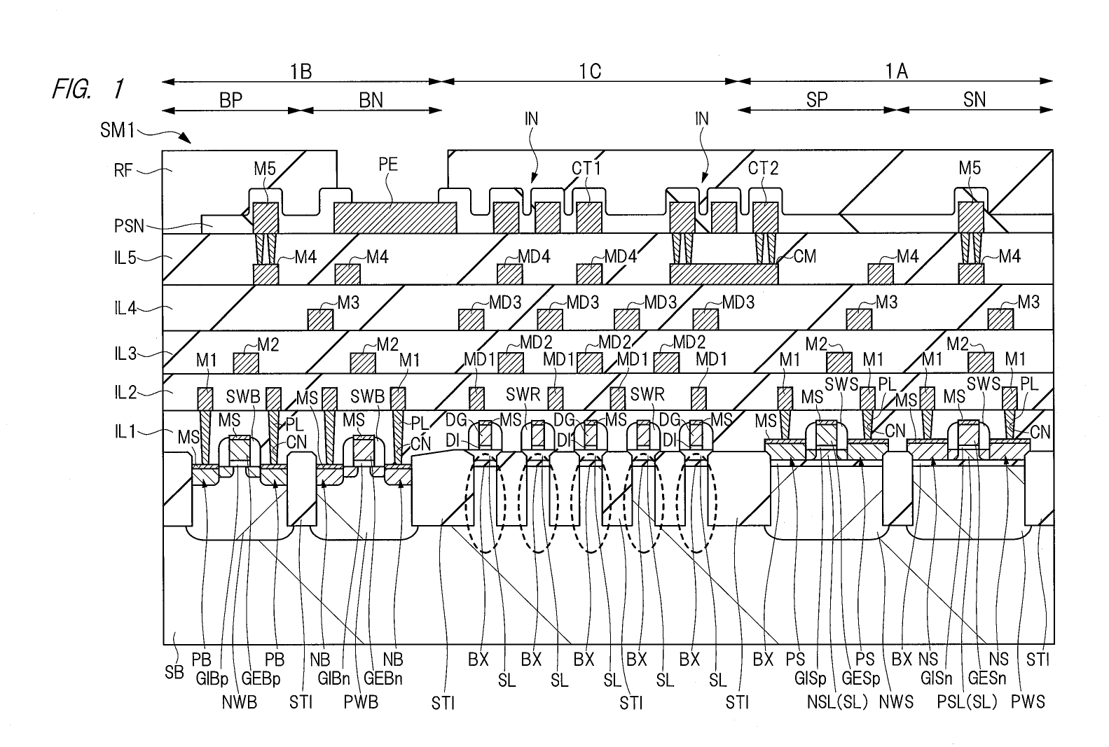

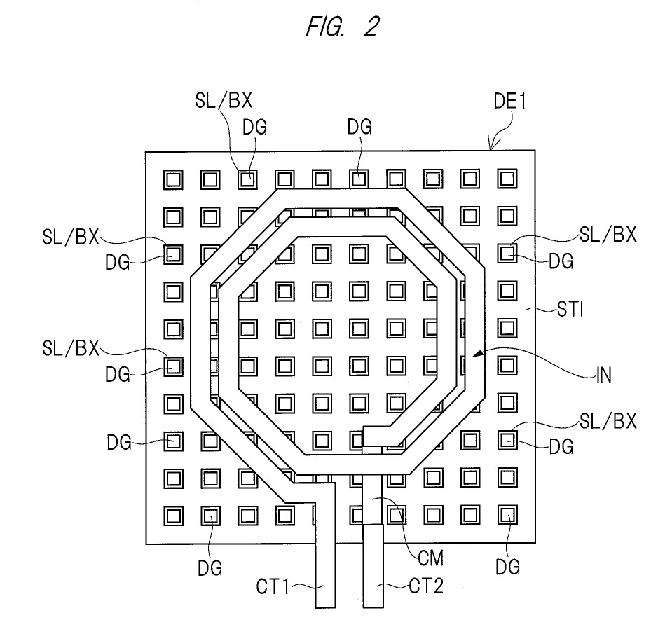

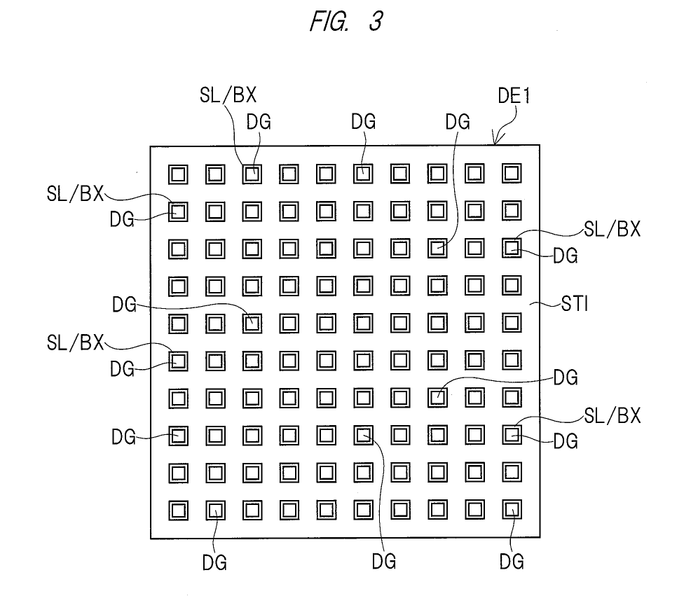

A configuration of a semiconductor device according to the first embodiment will be described with reference to FIG. 1 to FIG. 3. FIG. 1 is a cross-sectional view showing the semiconductor device according to the first embodiment. FIG. 2 is a plan view showing an inductor according to the first embodiment. FIG. 3 is a plan view showing a dummy element region located below the inductor according to the first embodiment.

In a semiconductor device SM1 according to the first embodiment, a SOI transistor, a bulk transistor, and an inductor formed in a circuit formation region will be illustrated.

In the first embodiment, a region in which SOI transistors (n channel SOI transistor SN and p channel SOI transistor SP) having a MOS (Metal Oxide Semiconductor) structure are formed is referred to as a SOI region 1A, and a region in which bulk transistors (n channel bulk transistor BN and p channel bulk transistor BP) having a MOS structure are formed is referred to as a bulk region 1B. Also, a region in which inductors IN are formed is referred to as an inductor region 1C.

In addition, though a multilayer wiring having five layers is illustrated in the description of the semiconductor device SM1 according to the first embodiment, the number of layers is not limited to this.

(1) Configuration of SOI Transistor

In the following description, then channel SOI transistor having the MOS structure is abbreviated as an n type SOI transistor, and the p channel SOI transistor having the MOS structure is abbreviated as a p type SOI transistor.

As shown in FIG. 1, the n type SOI transistor SN and the p type SOI transistor SP are formed on a main surface of a SOI substrate including a semiconductor substrate SB made of p type single crystal silicon, a BOX (Buried Oxide) layer (referred to also as a buried insulating layer) BX made of, for example, silicon oxide formed on the semiconductor substrate SB, and a semiconductor layer (referred to also as a SOI layer or silicon layer) SL made of single crystal silicon formed on the BOX layer BX. The BOX layer BX has a thickness of, for example, about 10 to 20 nm, and the semiconductor layer SL has a thickness of, for example, about 10 to 20 nm.

First, the n type SOI transistor SN will be described. The n type SOI transistor SN is isolated (insulated) from an adjacent element formation region (referred to also as an active region) by an element isolation portion STI formed in the semiconductor substrate SB, and a p type well PWS is formed in the semiconductor substrate SB where the n type SOI transistor SN is formed. Also, a p type semiconductor layer PSL is formed by introducing a p type impurity into the semiconductor layer SL where the n type SOI transistor SN is formed.

Agate insulating film GISn is formed on the p type semiconductor layer PSL, and a gate electrode GESn is formed on the gate insulating film GISn. The gate insulating film GISn is made of, for example, silicon oxide or silicon oxynitride, and the gate electrode GESn is made of, for example, polycrystalline silicon. The p type semiconductor layer PSL below the gate electrode GESn serves as a channel of the n type SOI transistor SN.

A sidewall spacer SWS made of an insulating material is formed on each side wall of the gate electrode GESn, and an epitaxial layer (not illustrated) is selectively formed on a region of the p type semiconductor layer PSL not covered with the gate electrode GESn and the sidewall spacer SWS.

Source and drain semiconductor regions NS of an n type conductivity of the n type SOI transistor SN are formed in the p type semiconductor layer PSL and the epitaxial layer on both sides of the gate electrode GESn (both sides in a gate length direction).

A silicide layer MS which is a reactive layer (compound layer) of metal and semiconductor is formed on the gate electrode GESn and on (a surface part of) the source and drain semiconductor regions NS.

A first interlayer insulating film IL1 is formed over the SOI substrate so as to cover the gate electrode GESn, the sidewall spacer SWS, and the silicide layer MS. A wiring M1 of a first layer is formed on the first interlayer insulating film IL1, and the wiring M1 is electrically connected to the gate electrode GESn, the source and drain semiconductor regions NS and others through plug electrodes PL buried in connection holes CN formed in the first interlayer insulating film IL1. The wiring M1 is made of, for example, copper or aluminum, and the plug PL is made of, for example, tungsten.

Further, a wiring M2 of a second layer, a wiring M3 of a third layer, a wiring M4 of a fourth layer, and a wiring M5 of a fifth layer are formed over the wiring M1 via a second interlayer insulating film IL2, a third interlayer insulating film IL3, a fourth interlayer insulating film IL4, and a fifth interlayer insulating film IL5, respectively. In addition, the wiring M5 of the uppermost fifth layer is covered with an insulating film PSN and a protection film RF. The insulating film PSN is made of, for example, silicon nitride, and the protection film RF is made of, for example, photosensitive polyimide.

Next, the p type SOI transistor SP will be described. The p type SOI transistor SP is isolated from an adjacent element formation region by the element isolation portion STI formed in the semiconductor substrate SB, and an n type well NWS is formed in the semiconductor substrate SB where the p type SOI transistor SP is formed. Also, an n type semiconductor layer NSL is formed by introducing an n type impurity into the semiconductor layer SL where the p type SOI transistor SP is formed.

Agate insulating film GISp is formed on the n type semiconductor layer NSL, and a gate electrode GESp is formed on the gate insulating film GISp. The gate insulating film GISp is made of, for example, silicon oxide or silicon oxynitride, and the gate electrode GESp is made of, for example, polycrystalline silicon. The n type semiconductor layer NSL below the gate electrode GESp serves as a channel of the p type SOI transistor SP.

A sidewall spacer SWS made of an insulating material is formed on each side wall of the gate electrode GESp, and an epitaxial layer (not illustrated) is selectively formed on a region of the n type semiconductor layer NSL not covered with the gate electrode GESp and the sidewall spacer SWS.

Source and drain semiconductor regions PS of a p type conductivity of the p type SOI transistor SP are formed in the n type semiconductor layer NSL and the epitaxial layer on both sides of the gate electrode GESp (both sides in a gate length direction).

A silicide layer MS which is a reactive layer of metal and semiconductor is formed on the gate electrode GESp and on (a surface part of) the source and drain semiconductor regions PS.

The first interlayer insulating film IL1 is formed over the SOI substrate so as to cover the gate electrode GESp, the sidewall spacer SWS, and the silicide layer MS like in the n type SOI transistor SN described above. The second to fifth interlayer insulating films IL2 to IL5 and the first to fifth wirings M1 to M5 of the first to fifth layers are further formed, and the wiring M5 of the uppermost fifth layer is covered with the insulating film PSN and the protection film RF.

(2) Configuration of Bulk Transistor

In the following description, an n channel bulk transistor with a MOS structure is abbreviated as an n type bulk transistor, and a p channel bulk transistor with a MOS structure is abbreviated as a p type bulk transistor.

As shown in FIG. 1, the n type bulk transistor BN and the p type bulk transistor BP are formed on a main surface of the semiconductor substrate SB made of p type single crystal silicon.

First, the n type bulk transistor BN will be described. The n type bulk transistor BN is isolated from an adjacent element formation region by the element isolation portion STI formed in the semiconductor substrate SB, and a p type well PWB is formed in the semiconductor substrate SB where the n type bulk transistor BN is formed.

A gate insulating film GIBn is formed on the semiconductor substrate SB (p type well PWB), and a gate electrode GEBn is formed on the gate insulating film GIBn. The gate insulating film GIBn is made of, for example, silicon oxide or silicon oxynitride, and the gate electrode GEBn is made of, for example, polycrystalline silicon. The semiconductor substrate SB below the gate electrode GEBn serves as a channel of the n type bulk transistor BN.

A sidewall spacer SWB made of an insulating material is formed on each side wall of the gate electrode GEBn.

Source and drain semiconductor regions NB of an n type conductivity of the n type bulk transistor BN are formed in the semiconductor substrate SB on both sides of the gate electrode GEBn (both sides in a gate length direction). The source and drain semiconductor regions NB each have a so-called LDD (Lightly Doped Drain) structure configured of an n type extension layer with a relatively low concentration and an n type diffusion layer with a relatively high concentration.

A silicide layer MS which is a reactive layer of metal and semiconductor is formed on the gate electrode GEBn and on (a surface part of) the source and drain semiconductor regions NB.

The first interlayer insulating film IL1 is formed over the semiconductor substrate SB so as to cover the gate electrode GEBn, the sidewall spacer SWB, and the silicide layer MS like in the n type SOI transistor SN described above. The second to fifth interlayer insulating films IL2 to IL5 and the first to fifth wirings M1 to M5 of the first to fifth layers are further formed, and the wiring M5 of the uppermost fifth layer is covered with the insulating film PSN and the protection film RF.

Next, the p type bulk transistor BP will be described. The p type bulk transistor BP is isolated from an adjacent element formation region by the element isolation portion STI formed in the semiconductor substrate SB, and an n type well NWB is formed in the semiconductor substrate SB where the p type bulk transistor BP is formed.

A gate insulating film GIBp is formed on the semiconductor substrate SB (n type well NWB), and a gate electrode GEBp is formed on the gate insulating film GIBp. The gate insulating film GIBp is made of, for example, silicon oxide or silicon oxynitride, and the gate electrode GEBp is made of, for example, polycrystalline silicon. The semiconductor substrate SB below the gate electrode GEBp serves as a channel of the p type bulk transistor BP.

A sidewall spacer SWB made of an insulating material is formed on each side wall of the gate electrode GEBp.

Source and drain semiconductor regions PB of a p type conductivity of the p type bulk transistor BP are formed in the semiconductor substrate SB on both sides of the gate electrode GEBp (both sides in a gate length direction). The source and drain semiconductor regions PB each have a so-called LDD structure configured of a p type extension layer with a relatively low concentration and a p type diffusion layer with a relatively high concentration.

A silicide layer MS which is a reactive layer of metal and semiconductor is formed on the gate electrode GEBp and on (a surface part of) the source and drain semiconductor regions PB.

The first interlayer insulating film IL1 is formed over the semiconductor substrate SB so as to cover the gate electrode GEBp, the sidewall spacer SWB, and the silicide layer MS like in the n type SOI transistor SN described above. The second to fifth interlayer insulating films IL2 to IL5 and the first to fifth wirings M1 to M5 of the first to fifth layers are further formed, and the wiring M5 of the uppermost fifth layer is covered with the insulating film PSN and the protection film RF.

Note that a pad electrode PE serving as a connection portion to the outside is formed of the wiring M5 of the uppermost fifth layer as shown in FIG. 1. The pad electrode PE is disposed in the bulk region 1B in FIG. 1, but is not limited to this.

(3) Configuration of Inductor Region

As shown in FIG. 1 and FIG. 2, the inductor IN is mainly formed of the wiring in the same layer as the wiring M5 of the uppermost fifth layer, and a winding axis of the inductor IN is perpendicular to the main surface of the semiconductor substrate SB.

The inductor IN is used as, for example, an antenna or an analog element (for example, coil). Each spiral constituting the inductor IN according to the first embodiment has a regular octagon shape. Also, the outermost spiral forms the largest regular octagon, and the inner spiral forms smaller regular octagon. Note that the spiral is not limited to the regular octagon, and may have a rectangular shape such as a square shape.

A first connection terminal CT1 serving as one terminal of the inductor IN is located in the same layer as the inductor IN and is connected to an outer peripheral end of the inductor IN, and is thus integrated with the inductor IN. On the other hand, a second connection terminal CT2 serving as the other terminal of the inductor IN is located in the same layer as the inductor IN, but is connected to an inner peripheral end of the inductor IN through a relay wiring CM made of a wiring in the layer different from that of the inductor IN (for example, wiring in the same layer as the wiring M4 of the fourth layer).

In the inductor region IC, a dummy element region DE1 in which a plurality of dummy elements are formed is provided on the main surface of the SOI substrate below the inductor IN in a plan view. In the first embodiment, the dummy element region DE1 has a rectangular planar shape, but the dummy element region DE1 is not limited to this and may have an octagon shape.

Hereinafter, a configuration of the dummy element region DE1 will be described in detail.

A plurality of dummy gate electrodes DG are formed in the dummy element region DE1. The dummy gate electrode DG is formed on the main surface of the SOI substrate including the semiconductor substrate SB made of p type single crystal silicon, the BOX layer BX formed on the semiconductor substrate SB, and the semiconductor layer SL made of single crystal silicon formed on the BOX layer BX, via a dummy gate insulating film DI. The dummy gate electrode DE is made of a material (for example, polycrystalline silicon film) in the same layer as the gate electrodes GEBn, GEBp, GESn, and GESp, and the dummy gate insulating film DI is made of a material (for example, silicon oxide film or silicon oxynitride film) in the same layer as the gate insulating films GISn and GISp.

A sidewall spacer SWR made of an insulating material is formed on each side wall of the dummy gate electrode DG, and a silicide layer MS which is a reactive layer of metal and semiconductor is formed on the dummy gate electrode DG. Note that the well like the p type well PWS or the n type well NWS formed in the SOI region 1A or the p type well PWB or the n type well NWB formed in the bulk region 1B is not formed in the semiconductor substrate SB below the BOX layer BX (regions indicated by dotted lines in FIG. 1).

Also, as shown in FIG. 1 and FIG. 3, the regions in which each of the plurality of dummy gate electrodes DG is formed are surrounded by the element isolation portion STI. In other words, the BOX layer BX and the semiconductor layer SL are separated into a plurality of regions by the element isolation portion STI in the dummy element region DE1, and the dummy gate electrode DG is formed on the semiconductor layer SL, which is located in each of the plurality of regions, via the dummy gate insulating film DI.

The plurality of dummy gate electrodes DG are arranged to form a two-dimensional matrix, and the dummy gate electrode DG is provided at each of the plurality of lattice points. The dummy gate electrode DG has a rectangular planar shape, for example, a square shape. Also, the dummy gate electrode DG is an isolated pattern.

The first interlayer insulating film IL1 is formed over the dummy element region DE1 so as to cover the dummy gate electrode DG, the sidewall spacer SWR, and the silicide layer MS. The second to fifth interlayer insulating films IL2 to IL5 and the dummy wirings MD1 to MD4 of the first to fourth layers are further formed. As described above, the relay wiring CM is configured of the wiring in the same layer as the wiring M4 of the fourth layer, and the inductor IN is configured of the wiring in the same layer as the wiring M5 of the uppermost fifth layer. The inductor IN is covered with the insulating film PSN and the protection film RF.

(4) Characteristics and Effect of Inductor Region

In the inductor region 1C according to the first embodiment, the dummy element region DE1 in which the dummy gate electrode DG is disposed in each of a plurality of regions defined by the element isolation portion STI is provided below the inductor IN in a plan view. Specifically, in each of the plurality of regions defined by the element isolation portion STI, the semiconductor substrate SB, the BOX layer BX formed on the semiconductor substrate SB, and the semiconductor layer SL formed on the BOX layer BX are formed, and the dummy gate electrode DG is formed on the semiconductor layer SL, which is located in each of the plurality of regions defined by the element isolation portion STI, via the dummy gate insulating film DI.

As described above, although the plurality of dummy gate electrodes DG are disposed in the dummy element region DE1 located below the inductor IN, since the dummy gate electrode DG is disposed in each of the plurality of regions defined by the element isolation portion STI, a total area of the plurality of dummy gate electrodes DG in a plan view is smaller than an area of the inductor region 1C. Further, since the dummy gate insulating film DI and the BOX layer BX are disposed between the dummy gate electrode DG and the semiconductor substrate SB and the well is not formed in the semiconductor substrate SB in the inductor region 1C, the impedance between the dummy gate electrode DG and the semiconductor substrate SB is increased.

Accordingly, the eddy current is generated in the dummy gate electrode DG in the dummy element region DE1 located below the inductor IN, but since the impedance between the dummy gate electrode DG and the semiconductor substrate SB is large, the eddy current is less likely to flow from the dummy gate electrode DG to the semiconductor substrate SB, so that the back electromotive force due to the generation of eddy current can be reduced.

Note that, even when the total area of the plurality of dummy gate electrodes DG according to the first embodiment is equal to the total area of the plurality openings formed in the element isolation film in Patent Document 1 mentioned above, the generation of eddy current can be more reduced in the structure of the inductor region 1C according to the first embodiment compared with the structure of the inductor region of Patent Document 1 mentioned above. Namely, in a cross-sectional view, the eddy current is generated only in the dummy gate electrode DG in the structure of the inductor region 1C according to the first embodiment, while the eddy current is generated in the dummy gate electrode, the dummy diffusion layer, and the well in the structure of Patent Document 1 mentioned above. Consequently, since the region where the eddy current is generated is smaller in the structure of the inductor region 1C according to the first embodiment than in the structure of the inductor region of Patent Document 1 mentioned above, it is possible to reduce the generation of the eddy current in the structure of the inductor region 1C according to the first embodiment.

In addition, since the plurality of dummy gate electrodes DG are formed in the inductor region 1C, it is possible to enhance the etching uniformity when the gate electrodes GESn and GESp are formed in the SOI region 1A and the gate electrodes GEBn and GEBp are formed in the bulk region 1B by processing a polycrystalline silicon film. Further, it is possible to enhance the flatness of the first interlayer insulating film IL1.

<<Manufacturing Method of Semiconductor Device>>

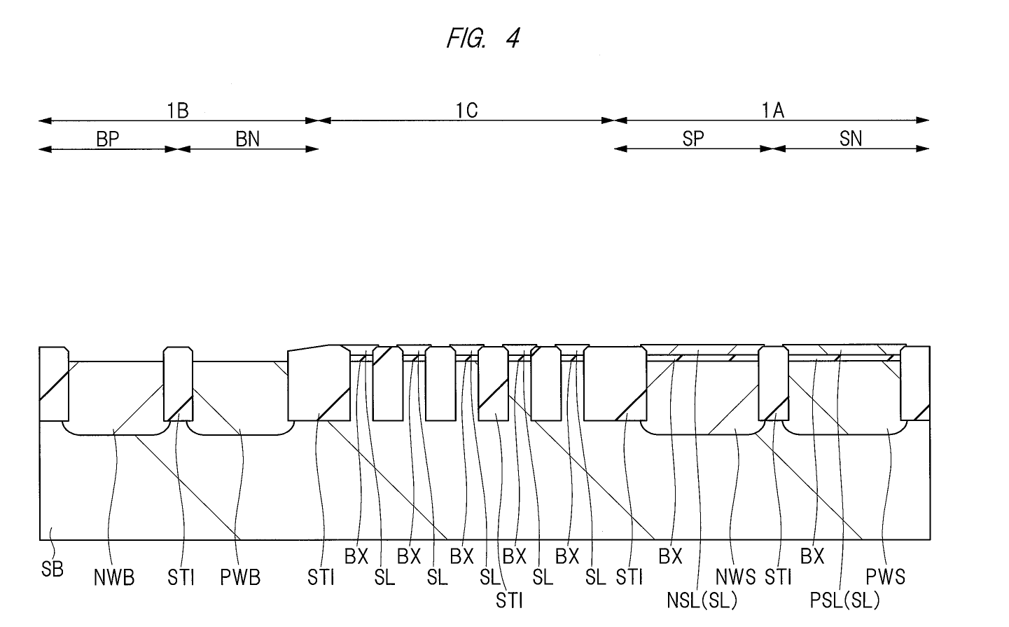

A manufacturing method of the semiconductor device according to the first embodiment will be described with reference to FIG. 4 to FIG. 8. FIG. 4 to FIG. 8 are cross-sectional views illustrating the manufacturing process of the semiconductor device according to the first embodiment.

First, as shown in FIG. 4, the SOI substrate including the semiconductor substrate SB, the BOX layer BX formed on the semiconductor substrate SB, and the semiconductor layer SL formed on the BOX layer BX is prepared. The semiconductor substrate SB is a support substrate made of Si (silicon), the BOX layer BX is made of silicon oxide, and the semiconductor layer SL is made of single crystal silicon with a resistance of about 1 to 10 Ωcm. The BOX layer BX has a thickness of, for example, about 10 to 20 nm, and the semiconductor layer SL has a thickness of, for example, about 10 to 20 nm.

Next, the element isolation portion STI made of an insulating film and having the STI (Shallow Trench Isolation) structure is formed in the SOI substrate. The element isolation portion STI is an inactive region which isolates the plurality of active regions of the SOI substrate from each other. Namely, the shape of the active region in a plan view is defined by being surrounded by the element isolation portion STI. In addition, the plurality of element isolation portions STI are formed so as to isolate the SOI region 1A, the bulk region 1B, and the inductor region 1C from one another. Further, the plurality of element isolation portions STI are formed so as to isolate adjacent element formation regions from each other in each of the SOI region 1A and the bulk region 1B, and the element isolation portion STI is formed so as to define the regions where the plurality of dummy gate electrodes DG described later are formed in the inductor region 1C.

Next, the p type well PWS is selectively formed by ion-implanting a p type impurity into the semiconductor substrate SB in the SOI region 1A where the n type SOI transistor SN is formed. At this time, though not illustrated, a threshold voltage control diffusion region of the n type SOI transistor SN is formed. Similarly, the n type well NWS is selectively formed by ion-implanting an n type impurity into the semiconductor substrate SB in the SOI region 1A where the p type SOI transistor SP is formed. At this time, though not illustrated, a threshold voltage control diffusion region of the p type SOI transistor SP is formed.

Next, the p type well PWB is selectively formed by ion-implanting a p type impurity into the semiconductor substrate SB in the bulk region 1B where the n type bulk transistor BN is formed. At this time, though not illustrated, a threshold voltage control diffusion region of the n type bulk transistor BN is formed. Similarly, the n type well NWB is selectively formed by ion-implanting an n type impurity into the semiconductor substrate SB in the bulk region 1B where the p type bulk transistor BP is formed. At this time, though not illustrated, a threshold voltage control diffusion region of the p type bulk transistor BP is formed.

Next, after a resist pattern is formed in the SOI region 1A and the inductor region 1C, the semiconductor layer SL in the bulk region 1B is selectively removed by, for example, the dry etching method using the BOX layer BX as a stopper. Then, the resist pattern is removed, and the BOX layer BX in the bulk region 1B is removed by, for example, hydrofluoric acid washing.

In the SOI region 1A, the bulk region 1B, and the inductor region 1C formed through the process described above, there is a step difference between a surface of the semiconductor layer SL in the SOI region 1A and the inductor region 1C and a surface of the semiconductor substrate SB in the bulk region 1B. However, since the step difference is no more than 20 nm and the occurrence of insufficient processing or breaking at the step difference portion can be prevented in the following manufacturing process, it is possible to form the SOI transistor and the bulk transistor by the same manufacturing process.

Next, the p type semiconductor layer PSL is selectively formed by ion-implanting a p type impurity into the semiconductor layer SL in the SOI region 1A where the n type SOI transistor SN is formed. Similarly, the n type semiconductor layer NSL is selectively formed by ion-implanting an n type impurity into the semiconductor layer SL in the SOI region 1A where the p type SOI transistor SP is formed.

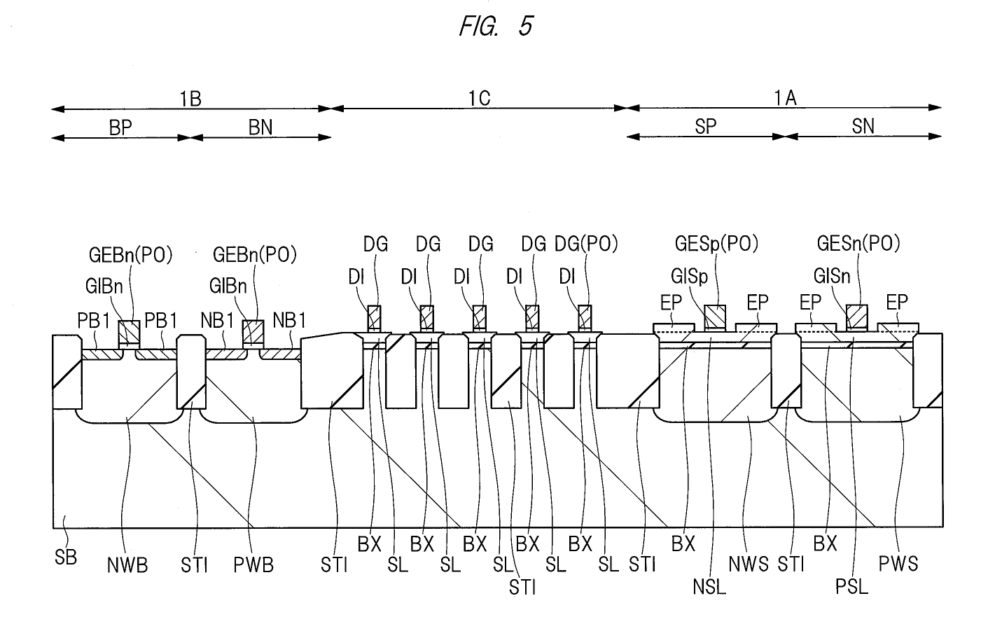

Then, as shown in FIG. 5, the gate insulating film GISn of the n type SOI transistor SN and the gate insulating film GISp of the p type SOI transistor SP are formed in the SOI region 1A, and the gate insulating film GIBn of the n type bulk transistor BN and the gate insulating film GIBp of the p type bulk transistor BP are formed in the bulk region 1B. Further, the dummy gate insulating film DI is formed in the inductor region 1C. The gate insulating films GISn and GISp and the dummy gate insulating film DI each have a thickness of, for example, about 2 to 3 nm, and the gate insulating films GIBn and GIBp each have a thickness of, for example, about 7 to 8 nm.

Thereafter, a polycrystalline silicon film PO and a silicon nitride film (not illustrated) are sequentially laminated by, for example, the CVD (Chemical Vapor Deposition) method on the gate insulating films GIBn, GIBp, GISn, and GISp and on the dummy gate insulating film DI. The polycrystalline silicon film PO has a thickness of, for example, about 40 nm, and the silicon nitride film has a thickness of, for example, about 30 nm.

Next, the silicon nitride film and the polycrystalline silicon film PO are sequentially processed by the anisotropic dry etching method using a resist pattern as a mask. Thus, the gate electrode GESn made of the polycrystalline silicon film PO of the n type SOI transistor SN and the gate electrode GESp made of the polycrystalline silicon film PO of the p type SOI transistor SP are formed in the SOI region 1A. At the same time, the gate electrode GEBn made of the polycrystalline silicon film PO of the n type bulk transistor BN and the gate electrode GEBp made of the polycrystalline silicon film PO of the p type bulk transistor BP are formed in the bulk region 1B. Further, the dummy gate electrode DG made of the polycrystalline silicon film PO is also formed in the inductor region 1C at the same time.

Next, an n type impurity, for example, As (arsenic) is ion-implanted into the semiconductor substrate SB in the bulk region 1B where the n type bulk transistor BN is formed. Thus, an n type extension layer NB1 of the n type bulk transistor BN is formed in a self-aligned manner. At this time, a p type halo region may be formed on a channel side of the n type extension layer NB1. The diffusion of the n type extension layer NB1 in the channel direction can be suppressed by providing the p type halo region in the n type bulk transistor BN.

Next, a p type impurity, for example, BF₂ (boron fluoride) is ion-implanted into the semiconductor substrate SB in the bulk region 1B where the p type bulk transistor BP is formed. Thus, a p type extension layer PB1 of the p type bulk transistor BP is formed in a self-aligned manner. At this time, an n type halo region may be formed on a channel side of the p type extension layer PB1. The diffusion of the p type extension layer PB1 in the channel direction can be suppressed by providing the n type halo region in the p type bulk transistor BP.

Next, a sidewall spacer (not illustrated) is formed on each of the side wall of the gate electrode GESn of the n type SOI transistor SN, the side wall of the gate electrode GESp of the p type SOI transistor SP, and the side wall of the dummy gate electrode DG. Subsequently, a stacked single crystal layer made of Si (silicon) or SiGe (silicon germanium), that is, an epitaxial layer EP is selectively formed by, for example, the selective epitaxial growth method on the p type semiconductor layer PSL and the n type semiconductor layer NSL exposed in the SOI region 1A.

Thereafter, the silicon nitride film on the sidewall spacers, the gate electrodes GEBn, GEBp, GESn, and GESp, and the dummy gate electrode DG described above is selectively removed.

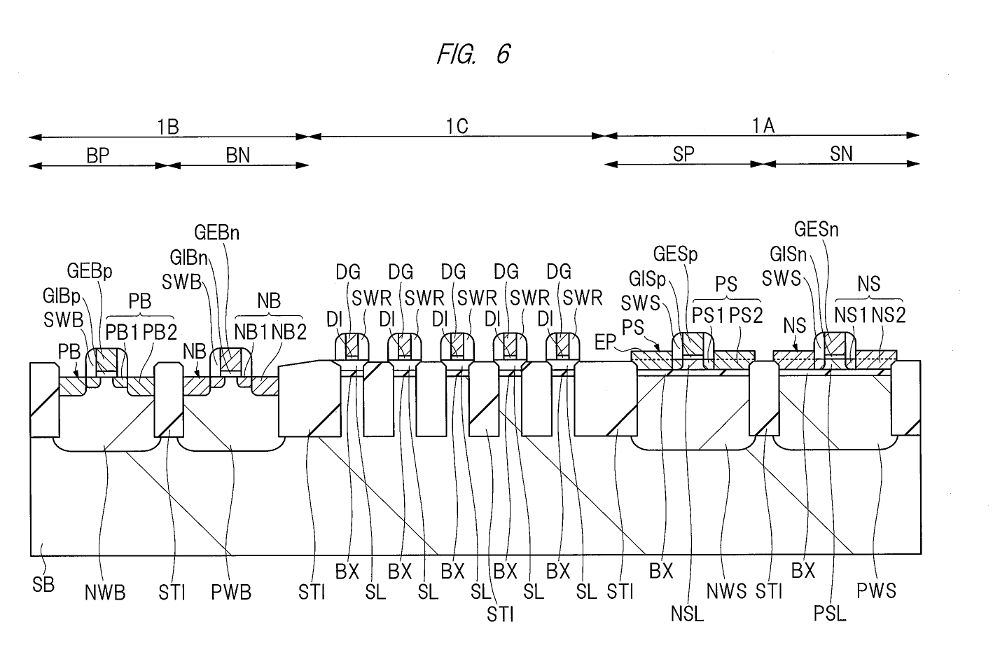

Next, as shown in FIG. 6, an n type impurity, for example, As (arsenic) is ion-implanted into the p type semiconductor layer PSL in the SOI region 1A where the n type SOI transistor SN is formed. Thus, an n type extension layer NS1 of the n type SOI transistor SN is formed in a self-aligned manner.

Next, a p type impurity, for example, BF₂ (boron fluoride) is ion-implanted into the n type semiconductor layer NSL in the SOI region 1A where the p type SOI transistor SP is formed. Thus, a p type extension layer PS1 of the p type SOI transistor SP is formed in a self-aligned manner.

Next, the sidewall spacer SWS is formed on each of the side wall of the gate electrode GESn of the n type SOI transistor SN and the side wall of the gate electrode GESp of the p type SOI transistor SP, and the sidewall spacer SWB is formed on each of the side wall of the gate electrode GEBn of the n type bulk transistor BN and the side wall of the gate electrode GEBp of the p type bulk transistor BP. At the same time, the sidewall spacer SWR is formed on the side wall of the dummy gate electrode DG.

Next, an n type impurity, for example, As (arsenic) is ion-implanted into the SOI region 1A and the bulk region 1B. Thus, an n type diffusion layer NS2 of the n type SOI transistor SN and an n type diffusion layer NB2 of the n type bulk transistor BN are formed in a self-aligned manner. Namely, the n type diffusion layer NS2 is formed by implanting an n type impurity into the epitaxial layer EP and the p type semiconductor layer PSL below the epitaxial layer EP in the n type SOI transistor SN, and the n type diffusion layer NB2 is formed by implanting an n type impurity into the semiconductor substrate SB in the n type bulk transistor BN. At this time, the n type impurity is not implanted into the channel regions below the gate electrodes GESn and GEBn.

Accordingly, the source and drain semiconductor regions NS each configured of the n type extension layer NS1 and the n type diffusion layer NS2 are formed in the n type SOI transistor SN, and the source and drain semiconductor regions NB each configured of the n type extension layer NB1 and the n type diffusion layer NB2 are formed in the n type bulk transistor BN.

Next, a p type impurity, for example, BF₂ (boron fluoride) is ion-implanted into the SOI region 1A and the bulk region 1B. Thus, a p type diffusion layer PS2 of the p type SOI transistor SP and a p type diffusion layer PB2 of the p type bulk transistor BP are formed in a self-aligned manner. Namely, the p type diffusion layer PS2 is formed by implanting a p type impurity into the epitaxial layer EP and the n type semiconductor layer NSL below the epitaxial layer EP in the p type SOI transistor SP, and the p type diffusion layer PB2 is formed by implanting a p type impurity into the semiconductor substrate SB in the p type bulk transistor BP. At this time, the p type impurity is not implanted into the channel regions below the gate electrodes GESp and GEBp.

Accordingly, the source and drain semiconductor regions PS each configured of the p type extension layer PS1 and the p type diffusion layer PS2 are formed in the p type SOI transistor SP, and the source and drain semiconductor regions PB each configured of the p type extension layer PB1 and the p type diffusion layer PB2 are formed in the p type bulk transistor BP.

Next, the ion-implanted impurities are activated and thermally diffused by, for example, the RTA (Rapid Thermal Anneal) method.

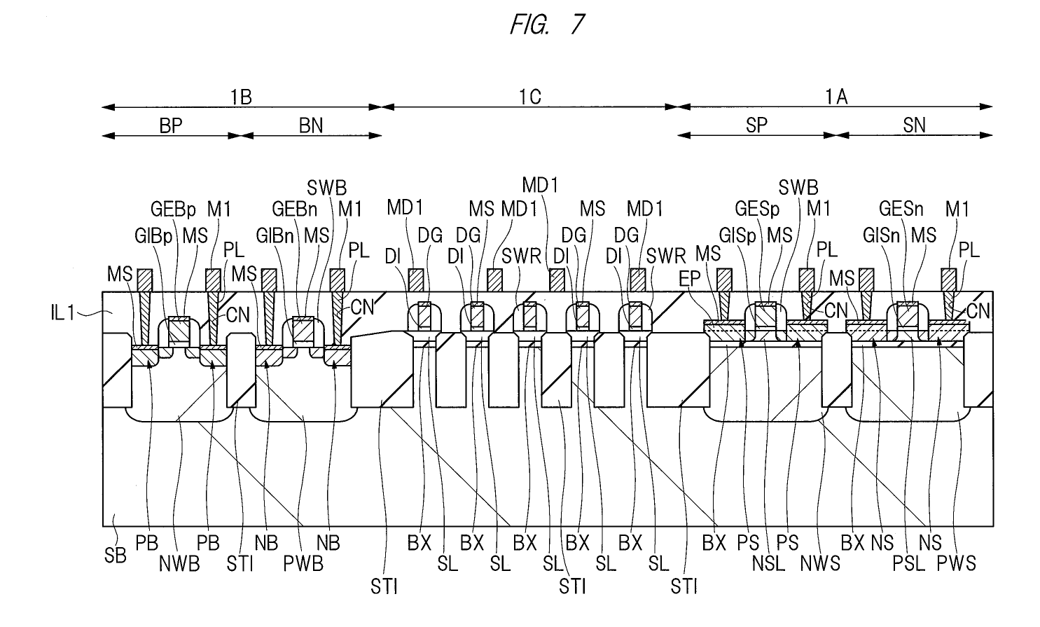

Next, as shown in FIG. 7, the silicide layer MS is formed. In the SOI region 1A, the silicide layer MS is formed on each of the gate electrode GESn and the source and drain semiconductor regions NS of the n type SOI transistor SN and each of the gate electrode GESp and the source and drain semiconductor regions PS of the p type SOI transistor SP. Also, in the bulk region 1B, the silicide layer MS is formed on each of the gate electrode GEBn and the source and drain semiconductor regions NB of the n type bulk transistor BN and each of the gate electrode GEBp and the source and drain semiconductor regions PB of the p type bulk transistor BP. In addition, the silicide layer MS is formed on the dummy gate electrode DG in the inductor region 1C.

Through the process described above, the n type SOI transistor SN having the gate electrode GESn and the source and drain semiconductor regions NS and the p type SOI transistor SP having the gate electrode GESp and the source and drain semiconductor regions PS are formed in the SOI region 1A. In addition, the n type bulk transistor BN having the gate electrode GEBn and the source and drain semiconductor regions NB and the p type bulk transistor BP having the gate electrode GEBp and the source and drain semiconductor regions PB are formed in the bulk region 1B. Further, the dummy gate electrode DG is formed in the inductor region 1C.

Next, after the first interlayer insulating film IL1 is formed over the semiconductor substrate SB so as to cover the SOI region 1A, the bulk region 1B, and the inductor region 1C, an upper surface of the first interlayer insulating film IL1 is planarized.

Next, the connection holes CN penetrating through the first interlayer insulating film IL1 are formed. The connection holes CN which reach the silicide layers MS formed on each of the gate electrode GESn and the source and drain semiconductor regions NS of the n type SOI transistor SN and each of the gate electrode GESp and the source and drain semiconductor regions PS of the p type SOI transistor SP are formed in the SOI region 1A. Also, the connection holes CN which reach the silicide layers MS formed on each of the gate electrode GEBn and the source and drain semiconductor regions NB of the n type bulk transistor BN and each of the gate electrode GEBp and the source and drain semiconductor regions PB of the p type bulk transistor BP are formed in the bulk region 1B.

Next, a barrier conductor film containing Ti (titanium) and a W (tungsten) film are sequentially formed over the first interlayer insulating film IL1 including the inside of the connection holes CN by, for example, the sputtering method. Thereafter, the barrier conductor film and the W (tungsten) film on the first interlayer insulating film IL1 are removed by, for example, the CMP (Chemical Mechanical Polishing) method, so that the columnar plug electrodes PL having the W (tungsten) film as a main conductor film are formed in the connection holes CN.

Subsequently, a metal film, for example, a Cu (copper) film or an Al (aluminum) film is formed over the first interlayer insulating film IL1 and the plug electrodes PL, and the metal film is then processed to form the wirings M1 of the first layer electrically connected to the plug electrodes PL. Further, the dummy wirings MD1 of the first layer which are not electrically connected to anything are formed in the inductor region 1C.

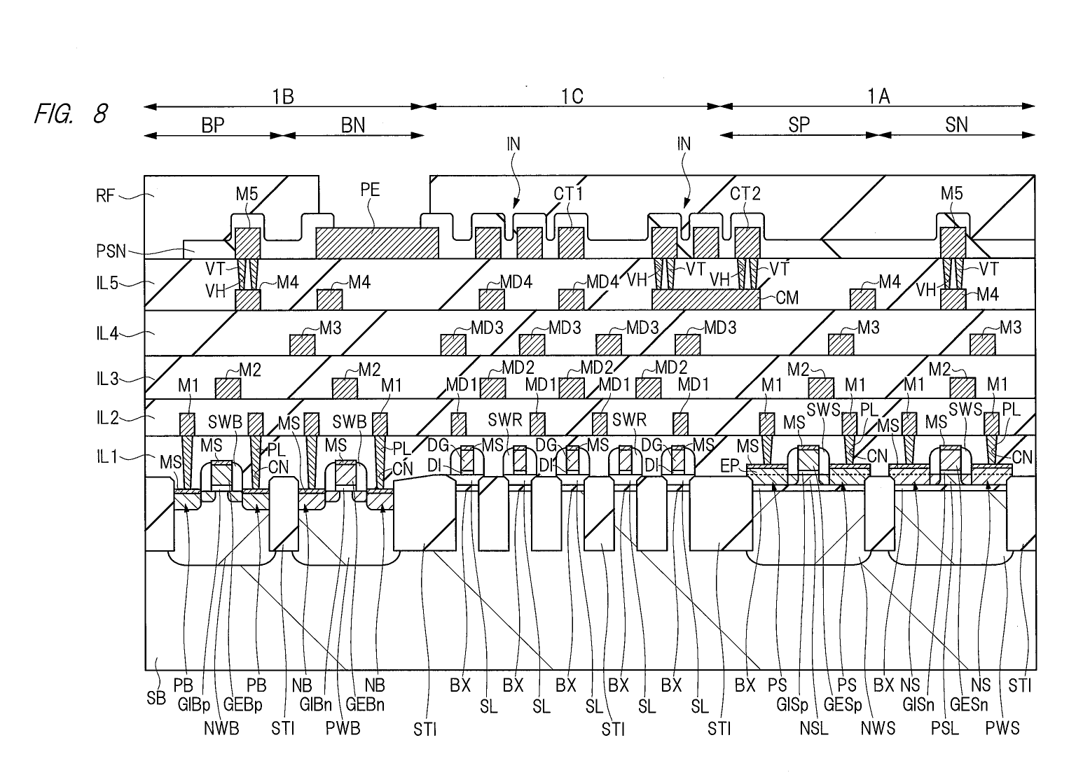

Next, as shown in FIG. 8, after the second interlayer insulating film IL2 is formed over the first interlayer insulating film IL1 so as to cover the wirings M1 and the dummy wirings MD1, an upper surface of the second interlayer insulating film IL2 is planarized. Since the plurality of dummy wirings MD1 are formed in the inductor region 1C, the flatness of the upper surface of the second interlayer insulating film IL2 is improved.

Next, after via holes (not illustrated) which penetrate through the second interlayer insulating film IL2 to reach the wirings M1 are formed, a first conductive film having a W (tungsten) film as a main conductor film is formed in the via holes. Subsequently, the wirings M2 of the second layer made of a metal film and electrically connected to the first conductive film are formed on the second interlayer insulating film IL2. Further, the dummy wirings MD2 of the second layer which are not electrically connected to anything are formed in the inductor region 1C. Since the plurality of dummy wirings MD2 are formed in the inductor region 1C, the flatness of an upper surface of the third interlayer insulating film IL3 described later is improved.

Further, after the third interlayer insulating film IL3 is formed over the second interlayer insulating film IL2 so as to cover the wirings M2 and the dummy wirings MD2 and via holes (not illustrated) which penetrate through the third interlayer insulating film IL3 to reach the wirings M2 are formed, a second conductive film having a W (tungsten) film as a main conductor film is formed in the via holes. Subsequently, the wirings M3 of the third layer made of a metal film and electrically connected to the second conductive film are formed on the third interlayer insulating film IL3. Further, the dummy wirings MD3 of the third layer which are not electrically connected to anything are formed in the inductor region 1C. Since the plurality of dummy wirings MD3 are formed in the inductor region 1C, the flatness of an upper surface of the fourth interlayer insulating film IL4 described later is improved.

Further, after the fourth interlayer insulating film IL4 is formed over the third interlayer insulating film IL3 so as to cover the wirings M3 and the dummy wirings MD3 and via holes (not illustrated) which penetrate through the fourth interlayer insulating film IL4 to reach the wirings M3 are formed, a third conductive film having a W (tungsten) film as a main conductor film is formed in the via holes. Subsequently, the wirings M4 of the fourth layer made of a metal film and electrically connected to the third conductive film are formed on the fourth interlayer insulating film IL4. Further, the relay wiring CM and the dummy wirings MD4 of the fourth layer which are not electrically connected to anything are formed in the inductor region 1C. Since the plurality of dummy wirings MD4 are formed in the inductor region 1C, the flatness of an upper surface of the fifth interlayer insulating film IL5 described later is improved.

Further, after the fifth interlayer insulating film IL5 is formed over the fourth interlayer insulating film IL4 so as to cover the wirings M4, the dummy wirings MD4, and the relay wiring CM and via holes VH which penetrate through the fifth interlayer insulating film IL5 to reach the wirings M4 or the relay wiring CM are formed, a fourth conductive film VT having a W (tungsten) film as a main conductor film is formed in the via holes VH. Subsequently, the wirings M5 of the fifth layer made of a metal film and electrically connected to the fourth conductive film VT and a pad electrode PE are formed on the fifth interlayer insulating film IL5, and the inductor IN, the first connection terminal CT1, and the second connection terminal CT2 are formed in the inductor region 1C.

Through the process described above, the multilayer wiring is formed in the SOI region 1A and the bulk region 1B. Also, the inductor IN is formed in the inductor region 1C.

Next, after the insulating film PSN made of, for example, silicon nitride is formed so as to cover the wirings M5, the pad electrode PE, and the inductor IN, the insulating film PSN on the pad electrode PE serving as a connection part to the outside is removed to expose an upper surface of the pad electrode PE. Subsequently, the protection film RF is formed over the insulating film PSN so as to expose the upper surface of the pad electrode PE. The protection film RF is made of, for example, photosensitive polyimide.

Through the process described above, the semiconductor device SM according to the first embodiment is mostly completed.

As described above, according to the first embodiment, the eddy current is generated in the dummy gate electrode DG in the dummy element region DE1 located below the inductor IN, but since the impedance between the dummy gate electrode DG and the semiconductor substrate SB is large, the eddy current is less likely to flow from the dummy gate electrode DG to the semiconductor substrate SB, so that the back electromotive force due to the generation of eddy current can be reduced. As a result, since the eddy current loss is reduced and the Q is increased, the characteristics of the inductor IN are improved.

### Second Embodiment

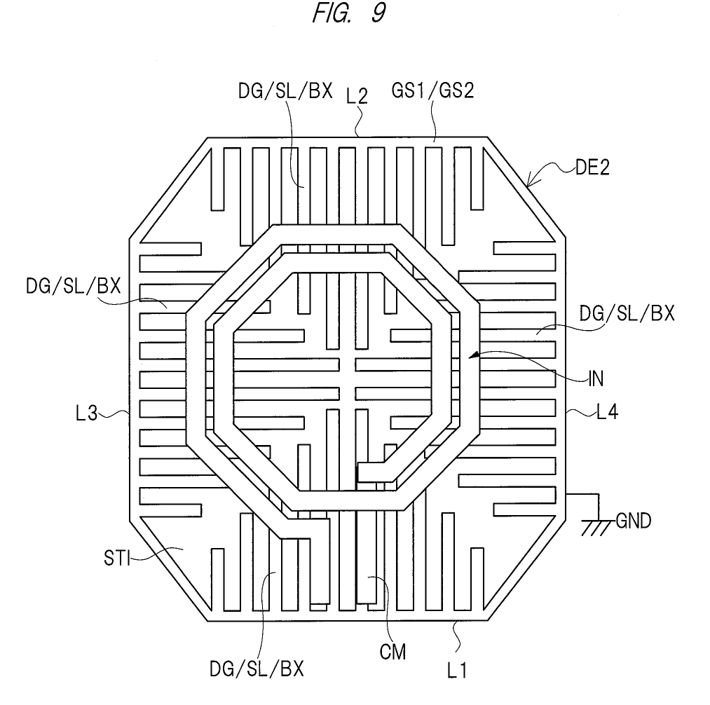

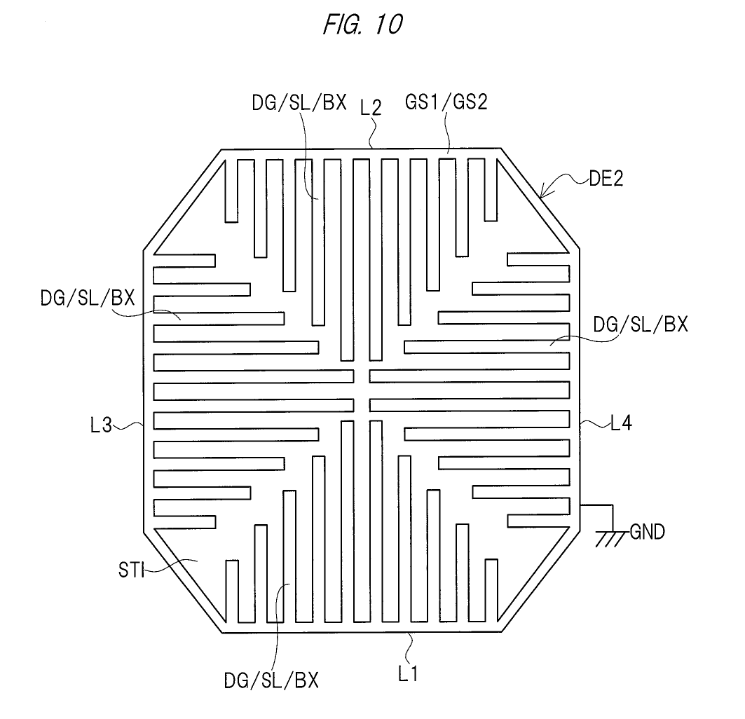

A configuration of a semiconductor device according to the second embodiment will be described with reference to FIG. 9 and FIG. 10. FIG. 9 is a plan view showing an inductor according to the second embodiment. FIG. 10 is a plan view showing a dummy element region located below the inductor according to the second embodiment.

A cross section of a dummy element region DE2 formed in the inductor region 1C of the semiconductor device according to the second embodiment is the same as that of the dummy element region DE1 formed in the inductor region 1C of the semiconductor device SM1 according to the first embodiment. Namely, the plurality of dummy gate electrodes DG are formed in the dummy element region DE2 according to the second embodiment. As shown in FIG. 1, the dummy gate electrode DG is formed on the main surface of the SOI substrate including the semiconductor substrate SB made of p type single crystal silicon, the BOX layer BX formed on the semiconductor substrate SB, and the semiconductor layer SL made of single crystal silicon formed on the BOX layer BX, via the dummy gate insulating film DI.

However, as shown in FIG. 9 and FIG. 10, in the dummy element region DE2 according to the second embodiment, the plurality of dummy gate electrodes DG are configured to have a rectangular shape with long sides and short sides in a plan view, and all of the plurality of dummy gate electrodes DG are fixed to the ground potential. Similarly, all of the plurality of semiconductor layers SL located below each of the plurality of dummy gate electrodes DG are also fixed to the ground potential. The plurality of dummy gate electrodes DG adjacent to each other are isolated by the element isolation portion STI, and the plurality of semiconductor layers SL adjacent to each other located below the dummy gate electrodes DG are also isolated by the element isolation portion STI.

Hereinafter, the configuration of the dummy element region DE2 will be described in detail.

A planar shape of the dummy element region DE2 is an octagon shape in a plan view, and a first ground wiring GS1 made of the same layer as the dummy gate electrode DG is disposed in the periphery of the dummy element region DE2. Also, the plurality of dummy gate electrodes DG extending to an inner side of the dummy element region DE2 from a first side L1 along a first direction, a second side L2 opposed to the first side L1, a third side L3 along a second direction orthogonal to the first direction, and a fourth side L4 opposed to the third side L3 in the periphery of the dummy element region DE2 are provided. The plurality of dummy gate electrodes DG are connected to the first ground wiring GS1 and are fixed to the ground potential.

Similarly, a second ground wiring GS2 made of the same layer as the semiconductor layer SL is disposed below the first ground wiring GS1 in the periphery of the dummy element region DE2. Also, the plurality of semiconductor layers SL extending to an inner side of the dummy element region DE2 from the first side L1, the second side L2, the third side L3, and the fourth side L4 in the periphery of the dummy element region DE2 are provided below the plurality of dummy gate electrodes DG. The plurality of semiconductor layers SL are connected to the second ground wiring GS2 and are fixed to the ground potential. Note that the planar shape of the dummy element region DE2 is not limited to the octagon shape, and may be a rectangular shape.

As described above, according to the second embodiment, the dummy gate electrode DG and the semiconductor layer SL formed in the dummy element region DE2 are fixed to the ground potential to reduce the resistance (Rg) of the dummy gate electrode DE and the semiconductor layer SL. Therefore, since the power consumed by the dummy gate electrode DG and the semiconductor layer SL (P=I²×Rg) is reduced if the current value (I) is not changed, the Q of the inductor IN is increased compared with the first embodiment described above, and the characteristics of the inductor IN are improved.

In the foregoing, the invention made by the inventors of the present invention has been concretely described based on the embodiments. However, it is needless to say that the present invention is not limited to the foregoing embodiments and various modifications and alterations can be made within the scope of the present invention.

What is claimed is:

1. A semiconductor device comprising:
a SOI substrate including a semiconductor substrate, a buried insulating film on the semiconductor substrate, and a semiconductor layer on the buried insulating film;
a multilayer wiring layer formed over a main surface of the SOI substrate; and
an inductor comprised of the multilayer wiring layer,
wherein, in a first region of the SOI substrate located below the inductor, the buried insulating film and the semiconductor layer are separated into a plurality of regions by an element isolation portion, and
wherein a dummy gate electrode is formed on a part of the semiconductor layer, which is located in each of the plurality of regions, via a dummy gate insulating film.

2. The semiconductor device according to claim 1,
wherein a planar shape of the element isolation portion in the first region is a lattice shape.

3. The semiconductor device according to claim 2,
wherein the dummy gate electrode is disposed in each of the regions separated by the element isolation portion with the lattice shape.

4. The semiconductor device according to claim 1,
wherein the dummy gate electrode is an isolated pattern.

5. The semiconductor device according to claim 1,
wherein a first outer peripheral portion made of a material in the same layer as the dummy gate electrode and fixed to a ground potential is provided in a periphery of the first region, and
wherein the dummy gate electrode is connected to the first outer peripheral portion.

6. The semiconductor device according to claim 5,
wherein the dummy gate electrode extends to an inner side of the first region from the first outer peripheral portion.

7. The semiconductor device according to claim 1,
wherein a first outer peripheral portion made of a material in the same layer as the dummy gate electrode and fixed to a ground potential is provided in a periphery of the first region,
wherein a second outer peripheral portion made of a material in the same layer as the semiconductor layer and fixed to the ground potential is provided in the periphery of the first region below the first outer peripheral portion,
wherein the dummy gate electrode is connected to the first outer peripheral portion, and
wherein the semiconductor layer below the dummy gate electrode is connected to the second outer peripheral portion.

8. The semiconductor device according to claim 7,
wherein the dummy gate electrode extends to an inner side of the first region from the first outer peripheral portion, and
wherein the semiconductor layer below the dummy gate electrode extends to the inner side of the first region from the second outer peripheral portion.

9. The semiconductor device according to claim 1,
wherein a well having an impurity concentration higher than that of the semiconductor substrate is not formed in the semiconductor substrate in the first region.

10. The semiconductor device according to claim 1,
wherein a transistor having a gate electrode on the semiconductor layer via a gate insulating film is provided in a second region of the SOI substrate which is not located below the inductor, and
wherein the dummy gate electrode and the gate electrode are made of a material in the same layer.

11. The semiconductor device according to claim 1,
wherein the inductor is comprised of a wiring of an uppermost layer.
